(19) United States
(12) Patent Application Publication
(10) Pub. No.: US 2023/0071618 A1
(43) Pub. Date: Mar. 9, 2023

(54) MEMORY DEVICE AND OPERATING METHOD OF THE MEMORY DEVICE

(71) Applicant: SK hynix Inc., Icheon-si Gyeonggi-do (KR)

(72) Inventors: Hyun Seob SHIN, Icheon-si Gyeonggi-do (KR); Dong Hun KWAK, Icheon-si Gyeonggi-do (KR)

(73) Assignee: SK hynix Inc., Icheon-si Gyeonggi-do (KR)

(21) Appl. No.: 17/676,545

(22) Filed: Feb. 21, 2022

(30) Foreign Application Priority Data
Sep. 9, 2021 (KR) 10-2021-0120457

(51) Int. Cl. G11C 11/56; G11C 16/10; G11C 16/24; G11C 16/34

(52) U.S. Cl. CPC G11C 11/5628; G11C 11/5671; G11C 16/10; G11C 16/24; G11C 16/3459

(57) ABSTRACT

A memory device includes: a plurality of memory cells; a peripheral circuit for performing a program operation including a plurality of loops each including a program voltage apply step and a verify step by using a plurality of verify voltages; and a program operation controller for controlling the peripheral circuit to perform the program operation. The program operation controller includes: a verify voltage controller for changing a verify voltage interval as an interval between the plurality of verify voltages from a predetermined target loop among the plurality of loops; and a bit line voltage controller to control bit line voltages applied to bit lines connected to first memory cells and second memory cells in the program voltage apply steps of an (n+1)th loop and an (n+2)th loop, based on a verify result in the verify step of an nth loop among the plurality of loops.

### CROSS-REFERENCE TO RELATED APPLICATION

The present application claims priority under 35 U.S.C. § 119(a) to Korean patent application number 10-2021-0120457, filed on Sep. 9, 2021, in the Korean Intellectual Property Office, the entire disclosure of which is incorporated herein by reference.

### BACKGROUND

### 1. Technical Field

The present disclosure generally relates to an electronic device, and more particularly, to a memory device and an operating method of the memory device.

### 2. Related Art

A storage device is a device which stores data under the control of a host device such as a computer or a smart phone. The storage device may include a memory device for storing data and a memory controller for controlling the memory device. The memory device is classified into a volatile memory device and a nonvolatile memory device.

The volatile memory device is a memory device in which data is stored only when power is supplied, and stored data disappears when the supply of power is interrupted. The volatile memory device may include a Static Random Access Memory (SRAM), a Dynamic Random Access Memory (DRAM), and the like.

The nonvolatile memory device is a memory device in which data does not disappear even when the supply of power is interrupted. The nonvolatile memory device may include a Read Only Memory (ROM), a Programmable ROM (PROM), an Electrically Programmable ROM (EPROM), an Electrically Erasable ROM (EEROM), a flash memory, and the like.

### SUMMARY

In accordance with an embodiment of the present disclosure, there is provided a memory device including: a plurality of memory cells; a peripheral circuit configured to perform a program operation including a plurality of loops each including a program voltage apply step of applying a program voltage to target cells among the plurality of memory cells and a verify step of verifying whether the target cells have been programmed by using a first verify voltage and a second verify voltage greater than the first verify voltage; and a program operation controller configured to control the peripheral circuit to perform the program operation, wherein the program operation controller includes: a verify voltage controller configured to change a verify voltage interval as an interval between the first verify voltage and the second verify voltage from a predetermined target loop among the plurality of loops; and a bit line voltage controller configured to control the peripheral circuit to apply a first bit line voltage to bit lines connected to first memory cells having a threshold voltage lower than the first verify voltage among the target cells and apply a second bit line voltage higher than the first bit line voltage to bit lines connected to second memory cells having a threshold voltage which is higher than or equal to the first verify voltage and is lower than the second verify voltage among the target cells in the program voltage apply step of an (n+1)th (n is a natural number equal to or greater than 2) loop, and apply the second bit line voltage to the bit lines connected to the first memory cells in the program voltage apply step of an (n+2)th loop, based on a verify result in the verify step of an nth loop as the target loop among the plurality of loops.

In accordance with an embodiment of the present disclosure, there is provided a method of operating a memory device for performing a program operation of applying a program voltage increased by a step voltage as a loop increases to a word line connected to target cells among a plurality of memory cells and performing a verify operation on the target cells by using a first verify voltage and a second verify voltage, the method including: performing the verify operation by changing, to a target interval, a verify voltage interval as an interval between the first verify voltage and the second verify voltage in an nth (n is a natural number equal to or greater than 2) loop among a plurality of loops from a default verify voltage interval as a verify voltage interval in a first loop to an (n−1)th loop among the plurality of loops, based on information on a predetermined target loop; performing the program operation by applying a first bit line voltage to bit lines connected to memory cells having a threshold voltage lower than the first verify voltage and applying a second bit line voltage higher than the first bit line voltage to bit lines connected to second memory cells having a threshold voltage which is greater than or equal to the first verify voltage and is lower than the second verify voltage in an (n+1)th loop among the plurality of loops, based on a result obtained by performing the verify operation in the nth loop; and performing a program operation by applying the second bit line voltage to the bit lines connected to the first memory cells in a (n+2)th loop among the plurality of loops.

In accordance with an embodiment of the present disclosure, there is provided a memory device including: a plurality of memory cells; a peripheral circuit configured to perform a program operation including a plurality of loops each including a program voltage apply step of applying a program voltage to target cells among the plurality of memory cells and a verify step of verifying whether the target cells have been programmed by using a plurality of verify voltages; and a program operation controller configured to control the peripheral circuit to change an interval between the plurality of verify voltages from a default interval to a target interval from a predetermined target loop among the plurality of loops, to determine each of bit line voltages to be applied to bit lines of the target cells in a program voltage apply step of an (n+1)th (n is a natural number equal to or greater than 2) loop and an (n+2)th loop, based on a verify result in an nth loop as the target loop, and to omit performance of a verify step in the (n+1)th loop and the (n+2)th loop.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a storage device in accordance with an embodiment of the present disclosure.

FIG. 2 is a diagram illustrating a structure of a memory device shown in FIG. 1.

FIG. 3 is a diagram illustrating an embodiment of a memory cell array shown in FIG. 2.

FIG. 4 is a circuit diagram illustrating any one memory block among memory blocks shown in FIG. 3.

FIG. 5 is a diagram illustrating a program operation in accordance with an embodiment of the present disclosure.

FIG. 6 is a diagram illustrating a pass loop according to a result obtained by comparing a fail bit number counted by a current sensing circuit with a reference number in accordance with an embodiment of the present disclosure.

FIG. 7 is a diagram illustrating omission of a verify operation in a second half loop in accordance with an embodiment of the present disclosure.

FIG. 8 is a diagram illustrating a double verify program operation in accordance with an embodiment of the present disclosure.

FIG. 9 is a diagram illustrating distribution degradation of memory cells in omission of a verify operation in a second half loop in the double verify program operation.

FIG. 10A is a diagram illustrating a distribution of memory cells according to a change in interval between two verify voltages.

FIG. 10B is a diagram illustrating a change in DPGM (Double verify PGM) effective bias according to an increase in level of a bit line voltage connected to target memory cells in accordance with an embodiment of the present disclosure.

FIG. 11 is a diagram illustrating a default verify voltage interval according to a magnitude of a step voltage and a magnitude of a default bit line voltage applied to a bit line connected to second memory cells.

FIG. 12 is a flowchart illustrating an operating method of the memory device in accordance with an embodiment of the present disclosure.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, examples of embodiments of the present disclosure will be described in detail with reference to the accompanying drawings.

Embodiments provide a memory device capable of reducing distribution degradation in a program operation of omitting a verify operation in a second half loop, in a program operation method in which a program operation is performed by using two verify voltages.

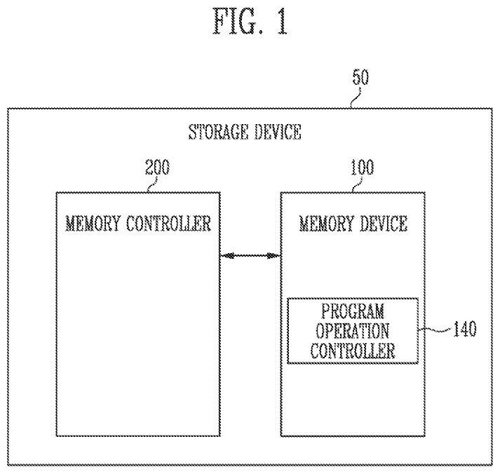

FIG. 1 is a diagram illustrating a storage device in accordance with an embodiment of the present disclosure.

Referring to FIG. 1, the storage device 50 may include a memory device 100 and a memory controller 200 configured to an operation of the memory device 100. The storage device 50 may be a device for storing data under the control of a host, such as a mobile phone, a smart phone, an MP3 player, a laptop computer, a desktop computer, a game console, a TV, a tablet PC or an in-vehicle infotainment.

The storage device 50 may be manufactured as any one of various types of storage devices according to a host interface that is a communication scheme with the host. For example, the storage device 50 may be implemented with any one of a variety of types of storage devices, such as a Solid State Drive (SSD), a Multi-Media Card (MMC), an Embedded MMC (eMMC), a Reduced Size MMC (RS-MMC), a micro-MMC (micro-MMC), a Secure Digital (SD) card, a mini-SD card, a micro-SD card, a Universal Serial Bus (USB) storage device, a Universal Flash Storage (UFS) device, a Compact Flash (CF) card, a Smart Media Card (SMC), a memory stick, and the like.

The storage device 50 may be manufactured as any one of various kinds of package types. For example, the storage device 50 may be manufactured as any one of various kinds of package types such as a Package-On-Package (POP), a System-In-Package (SIP), a System-On-Chip (SOC), a Multi-Chip Package (MCP), a Chip-On-Board (COB), a Wafer-level Fabricated Package (WFP), and a Wafer-level Stack Package (WSP).

The memory device 100 may store data. The memory device 100 operates under the control of the memory controller 200. The memory device 100 may include a memory cell array including a plurality of memory cells for storing data. The memory cell array may include a plurality of memory blocks. Each memory block may include a plurality of memory cells. One memory block may include a plurality of pages. In an embodiment, the page may be a unit for storing data in the memory device 100 or reading data stored in the memory device 100. The memory block may be a unit for erasing data. In an embodiment, the memory device 100 may be a Double Data Rate Synchronous Dynamic Random Access Memory (DDR SDRAM), a Low Power Double Data Rate 4 (LPDDR4) SDRAM, a Graphics Double Data Rate (GDDR) SRAM, a Low Power DDR (LPDDR), a Rambus Dynamic Random Access Memory (RDRAM), a NAND flash memory, a vertical NAND flash memory, a NOR flash memory, a Resistive Random Access Memory (RRAM), a Phase-Change Random Access Memory (PRAM), a Magnetoresistive Random Access Memory (MRAM), a Ferroelectric Random Access Memory (FRAM), a Spin Transfer Torque Random Access Memory (STT-RAM), or the like. In this specification, for convenience of description, a case where the memory device 100 is a NAND flash memory is assumed and described.

The memory device 100 receives a command and an address from the memory controller 200 and accesses an area selected by the address in the memory cell array. That is, the memory device 100 may perform an operation instructed by the command on the area selected by the address. For example, the memory device 100 may perform a write (program) operation, a read operation, and an erase operation. In the program operation, the memory device 100 may program data in the area selected by the address. In the read operation, the memory device 100 may read data from the area selected by the address. In the erase operation, the memory device 100 may erase data stored in the area selected by the address.

The memory controller 200 may control overall operations of the storage device 50.

When power is applied to the storage device 50, the memory controller 200 may execute firmware (FW). When the memory device 100 is a flash memory device, the memory controller 200 may execute FW such as a Flash Translation Layer (FTL) for controlling communication between the host and the memory device 100.

In an embodiment, the memory controller 200 may receive data and a Logical Block Address (LBA) from the host, and translate the LBA into a Physical Block Address (PBA) representing addresses of memory cells included in the memory device 100, in which data is to be stored.

The memory controller 200 may control the memory device 100 to perform a program operation, a read operation, an erase operation, or the like in response to a request from the host. In the program operation, the memory controller 200 may provide a program command, a PBA, and data to the memory device 100. In the read operation, the memory controller 200 may provide a read command and a PBA to the memory device 100. In the erase operation, the memory controller 200 may provide an erase command and a PBA to the memory device 100.

In an embodiment, the memory controller 200 may autonomously generate a command, an address, and data without any request from the host, and transmit the command, the address, and the data to the memory device 100. For example, the memory controller 200 may provide the command, the address, and the data to the memory device 100 to perform background operations such as a program operation for wear leveling and a program operation for garbage collection.

In an embodiment, the memory controller 200 may control at least two memory devices 100. The memory controller 200 may control the memory devices according to an interleaving scheme to improve operational performance.

The host may communicate with the storage device 50, using at least one of various communication manners, such as a Universal Serial bus (USB), a Serial AT Attachment (SATA), a High Speed InterChip (HSIC), a Small Computer System Interface (SCSI), Firewire, a Peripheral Component Interconnection (PCI), a PCI express (PCIe), a Non-Volatile Memory express (NVMe), a universal flash storage (UFS), a Secure Digital (SD), a Multi-Media Card (MMC), an embedded MMC (eMMC), a Dual In-line Memory Module (DIMM), a Registered DIMM (RDIMM), and a Load Reduced DIMM (LRDIMM).

In an embodiment, the memory device 100 may include a program operation controller 140.

The program operation controller 140 may control a peripheral circuit to perform a program operation on a plurality of memory cells. The program operation controller 140 may change a verify voltage interval as an interval between a first verify voltage and a second verify voltage from a predetermined target loop among a plurality of loops. The program operation controller 140 may determine voltages applied to bit lines respectively connected to first memory cells and second memory cells in (n+1)th and (n+2)th loops, based on a verify result in a verify step in the target loop among the plurality of loops. The program operation controller 140 may control the peripheral circuit to omit performance of the verify step in the (n+1)th loop and the (n+2)th loop. In an embodiment n may be a natural number equal to or greater than 2. The word “predetermined” as used herein with respect to a parameter, such as a predetermined target loop or predetermined loop, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

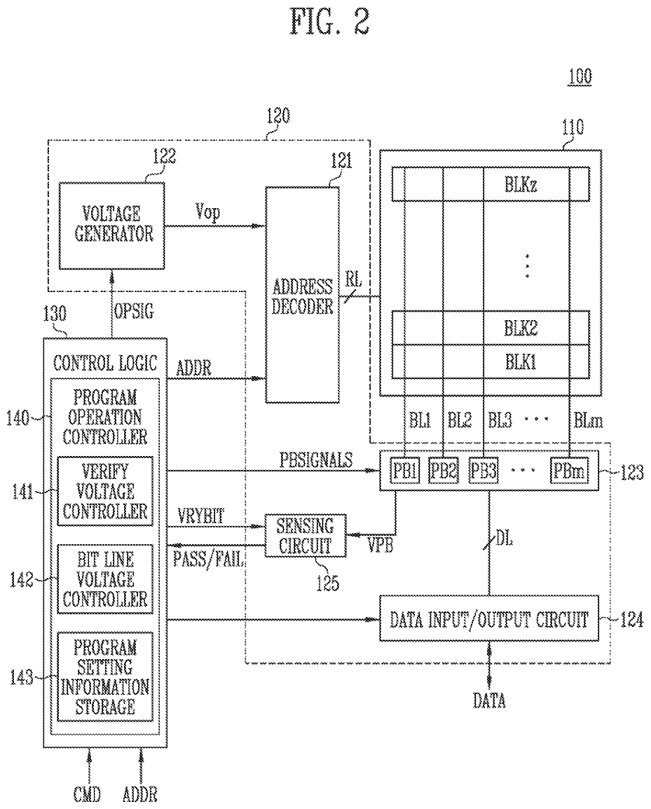

FIG. 2 is a diagram illustrating a structure of the memory device shown in FIG. 1.

Referring to FIG. 2, the memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 includes a plurality of memory blocks BLK1 to BLKz. The plurality of memory blocks BLK1 to BLKz are connected to an address decoder 121 through row lines RL. The plurality of memory blocks BLK1 to BLKz are connected to a read/write circuit 123 through bit lines BL1 to BLm. Each of the plurality of memory blocks BLK1 to BLKz includes a plurality of memory cells. In an embodiment, the plurality of memory cells may be nonvolatile memory cells. Memory cells connected to the same word line among the plurality of memory cells may be defined as one physical page. That is, the memory cell array 110 may be configured with a plurality of physical pages.

Each of the memory cells of the memory device may be configured as a Single Level Cell (SLC) storing one data bit, a Multi-Level Cell (MLC) storing two data bits, a Triple Level Cell (TLC) storing three data bits, or a Quad Level Cell (QLC) storing four data bits.

The peripheral circuit 120 may include the address decoder 121, a voltage generator 122, the read/write circuit 123, a data input/output circuit 124, and a sensing circuit 125.

The peripheral circuit 120 drives the memory cell array 110. For example, the peripheral circuit 120 may drive the memory cell array 110 to perform a program operation, a read operation, and an erase operation.

The address decoder 121 is connected to the memory cell array 110 through the row lines RL. The row lines RL may include drain select lines, word lines, source select lines, and a common source line. In accordance with an embodiment, the word lines may include normal word lines and dummy word lines. In accordance with an embodiment, the row lines RL may further include a pipe select line.

The address decoder 121 may operate under the control of the control logic 130. The address decoder 121 receives an address ADDR from the control logic 130.

The address decoder 121 may decode a block address in the received address ADDR. The address decoder 121 selects at least one memory block among the memory blocks BLK1 to BLKz according to the decoded block address. The address decoder 121 may decode a row address in the received address ADDR. The address decoder 121 may select at least one word line of the selected memory block by applying voltages provided from the voltage generator 122 to the at least one word line according to the decoded row address.

In a program operation, the address decoder 121 may apply a program voltage to the selected word line, and apply a pass voltage having a level lower than that of the program voltage to unselected word lines. In a program verify operation, the address decoder 121 may apply a verify voltage to the selected word line, and apply a verify pass voltage having a level higher than that of the verify voltage to the unselected word lines.

In a read operation, the address decoder 121 may apply a read voltage to the selected word line, and apply a read pass voltage having a level higher than that of the read voltage to the unselected word lines.

In accordance with an embodiment, an erase operation of the memory device 100 is performed in units of memory blocks. In an erase operation, the address ADDR input to the memory device 100 includes a block address. The address decoder 121 may decode the block address and select at least memory block according to the decoded block address. In the erase operation, the address decoder 121 may apply a ground voltage to word lines connected to the selected memory block.

In accordance with an embodiment, the address decoder 121 may decode a column address in the address ADDR transmitted thereto. The decoded column address may be transmitted to the read/write circuit 123. In an embodiment, the address decoder 121 may include components such as a row decoder, a column decoder, and an address buffer.

The voltage generator 122 may generate a plurality of voltages by using an external power voltage supplied to the memory device 100. The voltage generator 122 operates under the control of the control logic 130.

In an embodiment, the voltage generator 122 may generate an internal power voltage by regulating the external power voltage. The internal power voltage generated by the voltage generator 122 is used as an operation voltage of the memory device 100.

In an embodiment, the voltage generator 122 may generate a plurality of voltages by using the external power voltage or the internal power voltage. The voltage generator 122 may generate various voltages required by the memory device 100. For example, the voltage generator 122 may generate a plurality of erase voltages, a plurality of program voltages, a plurality of pass voltages, a plurality of select read voltages, and a plurality of unselect read voltages.

In order to generate a plurality of voltages having various voltage levels, the voltage generator 122 may include a plurality of pumping capacitors for receiving the internal power voltage, and generate the plurality of voltages by selectively activating the plurality of pumping capacitors under the control of the control logic 130.

The plurality of generated voltages may be supplied to the memory cell array 110 by the address decoder 121.

The read/write circuit 123 includes first to mth page buffers PB1 to PBm. The first to mth page buffers PB1 to PBm are connected to the memory cell array 110 through the respective first to mth bit lines BL1 to BLm. The first to mth page buffers PB1 to PBm operate under the control of the control logic 130.

The first to mth page buffers PB1 to PBm communicate data DATA with the data input/output circuit 124. In a program operation, the first to mth page buffers PB1 to PBm receive data DATA to be stored through the data input/output circuit 124 and data lines DL.

In a program operation, the first to mth page buffers PB1 to PBm may transfer, to selected memory cells through the bit lines BL1 to BLm, data DATA received through the data input/output circuit 124 when a program pulse is applied to a selected word line. The memory cells of the selected memory cells are programmed according to the transferred data DATA. A memory cell connected to a bit line through which a program allow voltage (e.g., a ground voltage) is applied may have an increased threshold voltage. A threshold voltage of a memory cell connected to a bit line through which a program inhibit voltage (e.g., a power voltage) is applied may be maintained. In a program verify operation, the first to mth page buffers PB1 to PBm read data DATA stored in the selected memory cells from the selected memory cells through the bit lines BL1 to BLm.

In a read operation, the read/write circuit 123 may read data DATA from memory cells of a selected page through the bit lines BL1 to BLm, and store the read data DATA in the first to mth page buffers PB1 to PBm.

In an erase operation, the read/write circuit 123 may float the bit lines BL1 to BLm. In an embodiment, the read/write circuit 123 may include a column select circuit.

The data input/output circuit 124 is connected to the first to mth page buffers PB1 to PBm through the data lines DL. The data input/output circuit 124 operates under the control of the control logic 130.

The data input/output circuit 124 may include a plurality of input/output buffers (not shown) that receive input data DATA. In a program operation, the data input/output circuit 124 may receive data DATA to be stored from an external controller (not shown). In a read operation, the data input/output circuit 124 outputs, to the external controller, data transmitted from the first to mth page buffers PB1 to PBm included in the read/write circuit 123.

In a read operation or verify operation, the sensing circuit 125 may generate a reference current in response to an allow bit VRYBIT signal generated by the control logic 130, and output a pass signal or fail signal to the control logic 130 by comparing a sensing voltage VPB received from the read/write circuit 123 and a reference voltage generated by the reference current.

In an embodiment, the sensing circuit 125 may include a current sensing circuit which counts a fail bit number as a number of cells of which program has failed among target cells. In an embodiment, the peripheral circuit may perform a program operation on the target cells among a plurality of memory cells. The program operation may include a plurality of loops each including a program voltage apply step and a verify step. In the program voltage apply step, a program voltage increased by a step voltage as a loop increases may be applied to a word line connected to the target cells. In the verify step, whether the target cells have been programmed may be checked by using two verify voltages.

The control logic 130 may be connected to the address decoder 121, the voltage generator 122, the read/write circuit 123, the data input/output circuit 124, and the sensing circuit 125. The control logic 130 may control overall operations of the memory device 100. The control logic 130 may operate in response to a command CMD transferred from an external device.

The control logic 130 may control the peripheral circuit 120 by generating several signals in response to a command CMD and an address ADDR. For example, the control logic 130 may generate an operation signal OPSIG, a row address RADD, a read/write circuit control signal PBSIGNALS, and an allow bit VRYBIT in response to the command CMD and the address ADDR. The control logic 130 may output the operation signal OPSIG to the voltage generator 122, output the row address RADD to the address decoder 121, output the read/write circuit control signal PBSIGNALS to the read/write circuit 123, and output the allow bit VRYBIT to the sensing circuit 125. Also, the control logic 130 may determine whether the verify operation has passed or failed in response to the pass or fail signal PASS/FAIL output by the sensing circuit 125.

The control logic 130 may include a program operation controller 140. The program operation controller 140 may include a verify voltage controller 141, a bit line voltage controller 142, and a program setting information storage 143.

The verify voltage controller 141 may adjust a verify voltage interval as an interval between two verify voltage in a double verify program (Double verify PGM). The verify voltage interval may mean an interval between a pre-verify voltage and a main verify voltage.

The verify voltage controller 141 may change the interval between the two verify voltages in a target loop, based on target loop information. The main verify voltage of the two verify voltages may be a verify voltage corresponding to a target state of a program operation. The pre-verify voltage of the two verify voltages may be a voltage for verifying a degree to which the program operation on a memory cell is performed at a level lower than that of the main verify voltage.

The verify voltage controller 141 may set a default verify voltage interval according to a magnitude of a step voltage, based on default verify voltage information. The default verify voltage information may be information on intervals of a default verify voltage corresponding to a plurality of step voltages. Specifically, the verify voltage controller 141 may set the default verify voltage interval to become wider as the magnitude of the step voltage becomes larger or increases.

The bit line voltage controller 142 may set a first bit line voltage applied to bit lines connected to first memory cells and a second bit line voltage applied to second memory cells among target cells on which the program operation is performed. In an embodiment, the first bit line voltage may be a ground voltage. The second bit line voltage may be a voltage higher than the first bit line voltage.

The first memory cells may be memory cells having a threshold voltage lower than a first verify voltage among the target cells. The first verify voltage may be the pre-verify voltage. The second memory cells may be memory cells having a threshold voltage which is higher than the first verify voltage or equal to and is lower than a second verify voltage among the target cells. The second verify voltage may be the main verify voltage.

In an embodiment, the bit line voltage controller 142 may set the second bit line voltage to be higher than a default bit line voltage after the target loop, based on the target loop information. In another embodiment, the bit line voltage controller 142 may set the second bit line voltage to be higher than the default bit line voltage, after a pass loop in which a fail bit number counted by the current sensing circuit is equal to or smaller than a reference number.

The bit line voltage controller 142 may set the default bit line voltage of the second bit line voltage to become higher as the step voltage increases, based on default bit line voltage information.

The program operation controller 140 may control the peripheral circuit 120 to perform a program operation on the target cells among the plurality of memory cells. The program operation may include a plurality of loops each including a program voltage apply step and a verify step. In the program voltage apply step, a program voltage increased by the step voltage as a loop increases may be applied to a word line connected to the target cells. In the verify step, it may be checked whether the target cells have been programmed by using the two verify voltages.

The program setting information storage 143 may store at least one of the target loop information, the default verify voltage information, and the default bit line voltage information.

The target loop information may be information on a target loop for changing a verify voltage interval as an interval between the pre-verify voltage and the main verify voltage from the default verify voltage interval among the plurality of loops. The target loop may be a predetermined loop. The default verify voltage information may be information on default verify voltage intervals corresponding to the plurality of step voltages. The default bit line voltage information on a default bit line voltage of a second bit line voltage corresponding to the plurality of step voltages.

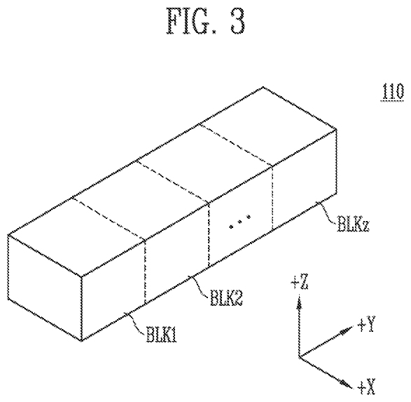

FIG. 3 is a diagram illustrating an embodiment of the memory cell array shown in FIG. 2.

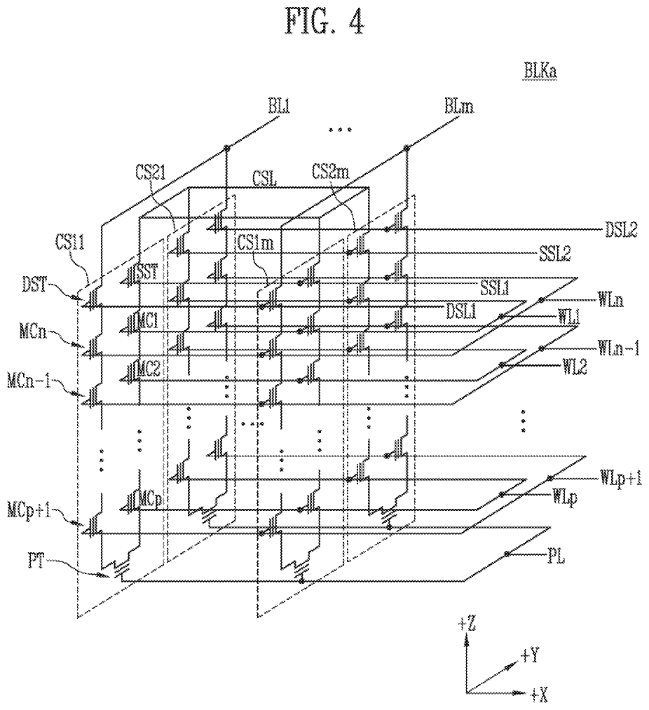

Referring to FIG. 3, the memory cell array 110 may include a plurality of memory blocks BLK1 to BLKz. Each memory block may have a three-dimensional structure. Each memory block may include a plurality of memory cells stacked on a substrate (not shown). The plurality of memory cells may be arranged along +X, +Y, and +Z directions. A structure of each memory block will be described in more detail with reference to FIG. 4.

FIG. 4 is a circuit diagram illustrating any one memory block BLKa among the memory blocks BLK1 to BLKz shown in FIG. 3.

Referring to FIG. 4, the memory block BLKa may include a plurality of cell strings CS11 to CS1m and CS21 to CS2m. In an embodiment, each of the plurality of cell strings CS11 to CS1m and CS21 to CS2m may be formed in a ‘U’ shape. In the memory block BLKa, m cell strings are arranged in a row direction (i.e., a +X direction). FIG. 4 illustrates two cell strings arranged in a column direction (i.e., a +Y direction). However, this is for convenience of description, and it will be understood that three cell strings may be arranged in the column direction.

Each of the plurality of cell strings CS11 to CS1m and CS21 to CS2m may include at least one source select transistor SST, first to nth memory cells MC1 to MCn, a pipe transistor PT, and at least one drain select transistor DST.

The select transistors SST and DST and the memory cells MC1 to MCn may have structures similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is connected between a common source line CSL and memory cells MC1 to MCp.

In an embodiment, the source select transistors of cell strings arranged on the same row are connected to a source select line extending in the row direction, and the source select transistors of cell strings arranged on different rows are connected to different source select lines. In FIG. 4, the source select transistors of the cell strings CS11 to CS1m on a first row are connected to a first source select line SSL1. The source select transistors of the cell strings CS21 to CS2m on a second row are connected to a second source select line SSL2.

In another embodiment, the source select transistors of the cell strings CS11 to CS1m and CS21 to CS2m may be commonly connected to one source select line.

The first to nth memory cells MC1 to MCn of each cell string are connected between the source select transistor SST and the drain select transistor DST.

The first to nth memory cells MC1 to MCn may be divided into first to pth memory cells MC1 to MCp and a (p+1)th to nth memory cells MCp+1 to MCn. The first to pth memory cells MC1 to MCp are sequentially arranged in the opposite direction of a +Z direction, and are connected in series between the source select transistor SST and the pipe transistor PT. The (p+1)th to nth memory cells MCp+1 to MCn are sequentially arranged in the +Z direction, and are connected in series between the pipe transistor PT and the drain select transistor DST. The first to pth memory cells MC1 to MCp and the (p+1)th to nth memory cells MCp+1 to MCn are connected through the pipe transistor PT. Gate electrodes of the first to nth memory cells MC1 to MCn of each cell string are connected to first to nth word lines WL1 to WLn, respectively.

A gate of the pipe transistor PT of each cell string is connected to a pipe line PL.

The drain select transistor DST of each cell string is connected between a corresponding bit line and the memory cells MCp+1 to MCn. Cell strings arranged in the row direction are connected to a drain select line extending in the row direction. The drain select transistors of the cell strings CS11 to CS1m on the first row are connected to a first drain select line DSL1. The drain select transistors of the cell strings CS21 to CS2m on the second row are connected to a second drain select line DSL2.

Cell strings arranged in the column direction are connected to a bit line extending in the column direction. In FIG. 4, the cell strings CS11 and CS21 on a first column are connected to a first bit line BL1. The cell strings CS1m and CS2m on an mth column are connected to an mth bit line BLm.

Memory cells connected to the same word line in the cell strings arranged in the row direction constitute one page. For example, memory cells connected to the first word line WL1 in the cell strings CS11 to CS1m on the first row constitute one page. Memory cells connected to the first word line WL1 in the cell strings CS21 to CS2m on the second row constitute another page. As any one of the drain select lines DSL1 and DSL2 is selected, cell strings arranged in one row direction may be selected. As any one of the word lines WL1 to WLn is selected, one page may be selected in the selected cell strings.

In another embodiment, even bit lines and odd bit lines may be provided instead of the first to mth bit lines BL1 to BLm. In addition, even-numbered cell strings among the cell strings CS11 to CS1m or CS21 to CS2m arranged in the row direction may be connected to the even bit lines, respectively, and odd-numbered cell strings among the cell strings CS11 to CS1m or CS21 to CS2m arranged in the row direction may be connected to the odd bit lines, respectively.

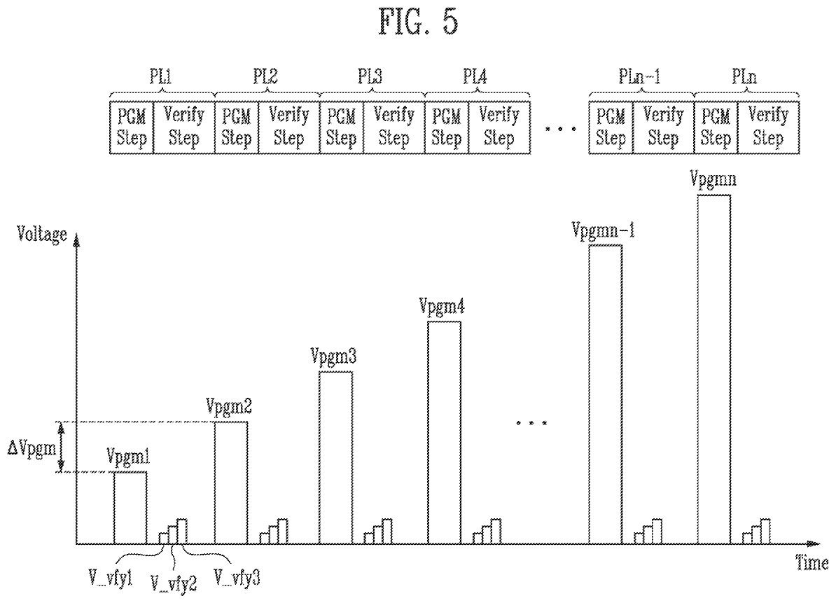

FIG. 5 is a diagram illustrating a program operation in accordance with an embodiment of the present disclosure.

Referring to FIG. 5, the program operation may include a plurality of program loops PL1 to PLn. The memory device may program selected memory cells to have any one program state among a plurality of program states by performing the plurality of program loops PL1 to PLn.

Each of the plurality of program loops PL1 to PLn may include a program voltage apply step PGM Step of applying a program voltage and a verify step Verify Step of determining whether memory cells have been programmed by applying verify voltages.

In the program voltage apply step, a program voltage apply step of applying a program voltage to a selected word line connected to selected memory cells may be performed. The selected memory cells may be programmed to any one program state among first to nth (n is a natural number) states by the program voltage apply operation.

In an embodiment, the program voltage may be determined according to an incremental step pulse programming (ISPP) scheme. That is, a level of the program voltage may be step wisely increased or decreased by a step voltage as program loops are repeated. The application numbers, voltage levels, voltage application times, and the like of program voltages used in the respective program loops may be determined in various forms under the control of the memory controller.

A pass voltage may be applied to unselected word lines as the other word lines except the selected word line. In an embodiment, pass voltages having the same level may be applied to the unselected word lines. In an embodiment, the pass voltage may have different levels according to the position of a word line.

A ground voltage as a program allow voltage may be applied to selected bit lines connected to memory cells to be programmed. A program inhibit voltage may be applied to unselected bit lines as bit lines connected to memory cells except the memory cells to be programmed.

In the verify step, the memory device may apply a verify voltage to the selected word line, and apply a verify pass voltage to the unselected word lines. The memory device may sense a voltage or current output through bit lines to which the memory cells connected to the selected word line are respectively connected, and determine whether the verify step has passed or failed based on the sensed result.

In the verify step, a program verify operation on at least one program state among the first to nth program states may be performed. For example, when memory cells to be programmed to a kth (k is a natural number which is equal to or greater than 1 and is equal to or less than n) state are read as off-cells by a verify voltage corresponding to the kth state, the program verify operation on the kth state may pass.

In FIG. 5, when each of the selected memory cells is a Multi-Level Cell (MLC) storing two data bits, the selected memory cells may be programmed to any one program state among an erase state and first to third program states. The number of data bits stored by the memory cell is not limited to this embodiment.

When a first program loop PL1 is performed, first to third verify voltages V_vfy1 to V_vfy3 may be sequentially applied to verify a program state of a plurality of memory cells after a first program voltage Vpgm1 is applied. Memory cells of which target program state is a first program state may be verified by the first verify voltage V_vfy1, memory cells of which target program state is a second program state may be verified by the second verify voltage V_vfy2, and memory cells of which target program state is a third program state may be verified by the third verify voltage V_vfy3. The number of verify voltages is not limited to this embodiment.

It may be determined that the memory cells which have verify-passed by each of the verify voltages V_vfy1 to V_vfy3 have the target program state. Then, the memory cells may be program-inhibited in a second program loop PL2. The program inhibit voltage may be applied to a bit line connected to the program-inhibited memory cells. A second program voltage Vpgm2 higher by a unit voltage ΔVpgm than the first program voltage Vpgm1 may be applied to the selected word line in the second program loop PL2.

Subsequently, a verify operation may be performed identically to the verify operation of the first program loop PL1. The verify pass indicates that a memory cell is read as an off-cell by a corresponding verify voltage.

As described above, when the memory device programs a Multi-Level Cell (MLC), the memory device verify memory cells having program states as target program states by respectively using the first to third verify voltages V_vfy1 to V_vfy3.

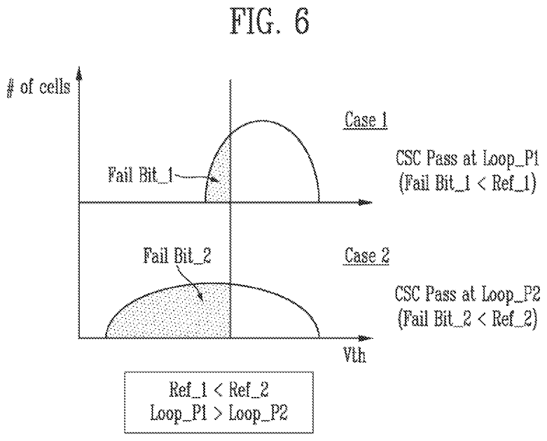

FIG. 6 is a diagram illustrating a pass loop according to a result obtained by comparing a fail bit number counted by the current sensing circuit with a reference number in accordance with an embodiment of the present disclosure.

The current sensing circuit (CSC) described with reference to FIG. 2 may count a fail bit number as a number of cells which have program-failed among target cells on which a program operation is performed. When the fail bit number is less than or equal to a reference number, a current sensing verify operation may pass. When the current sensing verify operation passes, a verify operation may be omitted in a subsequent program loop. When the fail bit number is greater than the reference number, the current sensing verify operation may fail. The reference number may be variously set in some embodiments.

A pass loop may be a loop in which the fail bit number is less than or equal to the reference number among a plurality of program loops. When the plurality of program loops are performed, a loop count of the pass loop may become smaller as the reference number becomes larger.

For example, in a first case Case 1, a fail bit number Fail Bit_1 is less than a reference number Ref 1, and hence a loop Loop_P1 may be the pass loop. In a second case Case 2, a fail bit number Fail Bit_2 is less than a reference number Ref 2, and hence a loop Loop_P2 may be the pass loop.

When a program loop is equally performed in the first and second cases Case 1 and Case 2, the reference number Ref_1 is less than the reference number Ref_2, and hence the current sensing verify operation may pass earlier in the second case Case 2 than the first case Case 1. Therefore, a count of the loop Loop_P2 as the pass loop may be less than that of the loop Loop_P1 as the pass loop.

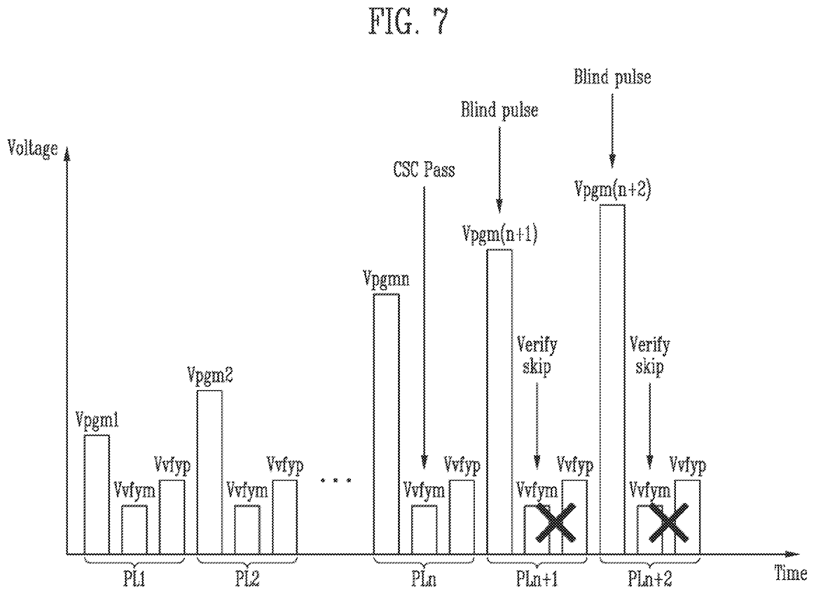

FIG. 7 is a diagram illustrating omission of a verify operation in a second half loop in accordance with an embodiment of the present disclosure.

As described with reference to FIG. 5, a program operation may include a plurality of program loops PL1 to PLn+2. Each of the plurality of program loops PL1 to PLn+2 may include a program voltage apply step PGM Step of applying a program voltage and a verify step Verify Step of determining whether memory cells have been programmed by applying verify voltages.

In accordance with an embodiment of the present disclosure, in the verify step, the memory device may perform a verify operation on target cells by using a pre-verify voltage Vvfyp and a main verify voltage Vvfym.

In accordance with an embodiment, each of first to nth loops PL1 to PLn may include the program voltage apply step PGM Step and the verify step Verify Step. Each of (n+1)th and (n+2)th loops PLn+1 and PLn+2 may include the program voltage apply step PGM Step. The verify step Verify Step may be omitted in the (n+1)th and (n+2)th loops PLn+1 and PLn+2.

In some embodiments, the verify step Verify Step is omitted in the (n+1)th and (n+2)th loops PLn+1 and PLn+2, so that a total program time can decrease. The verify step Verify Step is omitted in the (n+1)th and (n+2)th loops PLn+1 and PLn+2, and therefore, distribution degradation of the target cells may increase.

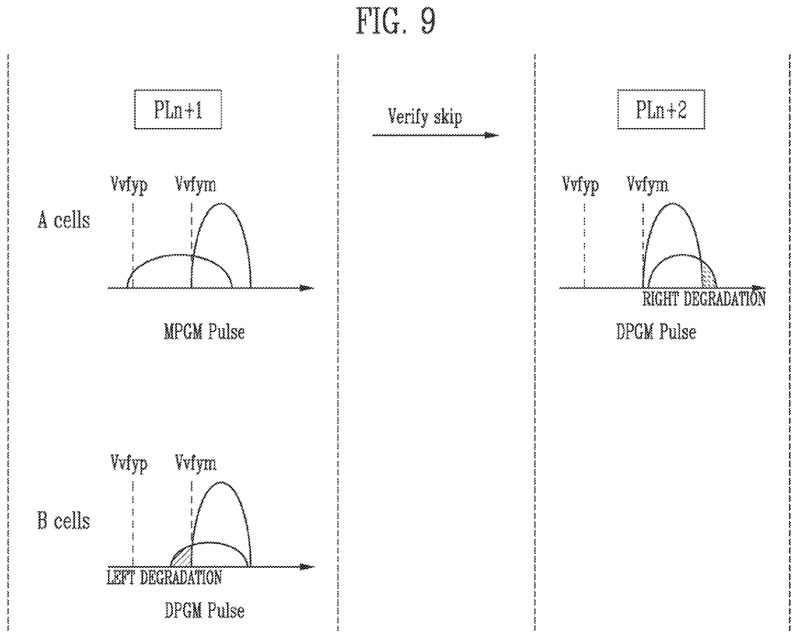

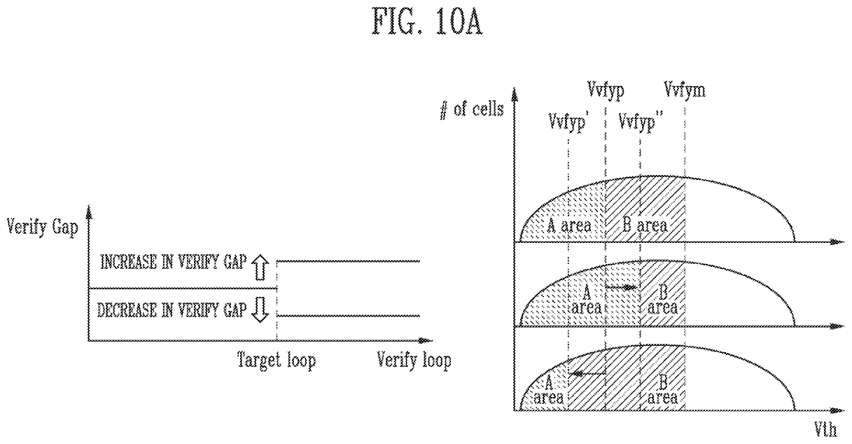

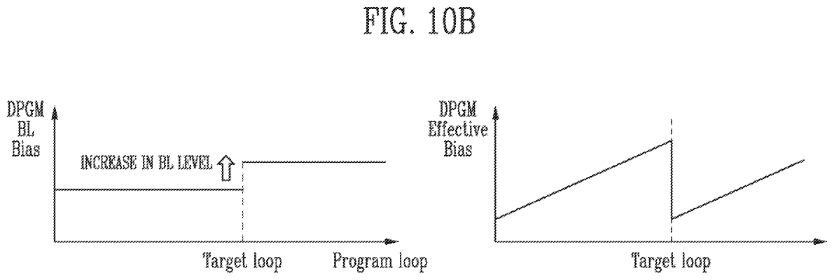

The distribution degradation of the target cells will be described later in FIG. 9. An embodiment for decreasing the distribution degradation of the target cells will be described with reference to FIGS. 10 to 12.

In an embodiment, a program operation of performing a verify operation by using two verify voltage levels is described as an example, but the number of verify voltages used in the program operation is not limited to this embodiment.

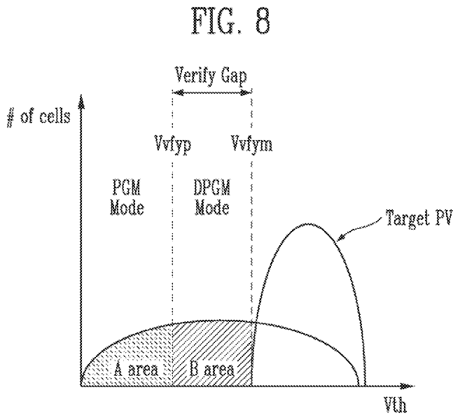

FIG. 8 is a diagram illustrating a double verify program operation in accordance with an embodiment of the present disclosure.

Referring to FIG. 8, the double verify program operation (Double verify PGM) may be a program operation of performing a verify operation on a program operation by using two verify voltage levels in the verify operation. The two verify voltages may be a pre-verify voltage Vvfyp and a main verify voltage Vvfym. The main verify voltage Vvfym may be a verify voltage corresponding to a target program state of a memory cell. The pre-verify voltage Vvfyp may be a voltage for verifying a degree to which the program operation on the memory cell is performed at a level lower than that of the main verify voltage Vvfym.

A state mode of the memory cell may be determined according to a verify result of the program operation. The state mode may include a first state mode PGM Mode and a second state mode DPGM Mode.

A threshold voltage of first memory cells A cells as the first state mode PGM Mode is lower than the pre-verify voltage Vvfyp, and hence it is necessary to rapidly perform the program operation to reach the target program state Target PV. A threshold voltage of second memory cells B cells as the second state mode DPGM Mode is higher than the pre-verify voltage Vvfyp and is lower than the main verify voltage Vvfym, and hence it is necessary to slowly perform the program operation, as compared with the first memory cells A cells, to reach the target program state Target PV.

Therefore, in the program operation, a first effective bias may be applied to the first memory cells A cells in the first state mode PGM Mode, and a second effective bias lower than the first effective bias may be applied to the second memory cells B cells in the second state mode DPGM mode.

In order to apply the second effective bias lower than the first effective bias to the second memory cells B cells, a first bit line voltage may be applied to bit lines connected to the first memory cells A cells and a second bit line voltage may be applied to bit lines connected to the second memory cells B cells, while a program pulse is applied to a word line connected to target memory cells.

The first bit line voltage may be a ground voltage. The second bit line voltage may be a voltage higher than the first bit line voltage. The second memory cells B cells has a potential difference between a word line and a bit line, which is smaller than that of the first memory cells A cells, and therefore, an effective bias lower than that of the first memory cells A cells may be applied to the second memory cells B cells. In an embodiment, although the program operation of performing the verify operation by using the two verify voltage levels has been described as an example, the number of verify voltages used in the program operation is not limited to this embodiment.

FIG. 9 is a diagram illustrating distribution degradation of memory cells in omission of a verify operation in a second half loop in the double verify program operation.

Referring to FIG. 9, when the verify operation described with reference to FIG. 8 is a verify operation of the nth loop PLn, distribution degradation of the target cells in the (n+1)th loop PLn+1 and (n+2)th loop PLn+2 is illustrated.

In FIG. 9, the nth loop PLn may be a predetermined target loop. The target loop may be a loop for changing an interval between the pre-verify voltage and the main verify voltage from a default verify voltage interval. In another embodiment, the nth loop PLn may be a loop in which a current sensing verify operation passes (CSC Pass). Therefore, the verify step may be omitted in a subsequent loop as a loop after the nth loop PLn. That is, the verify step may be omitted in the (n+1)th loop PLn+1 and (n+2)th loop PLn+2.

The first memory cells A cells may be memory cells determined to be in the first state mode PGM Mode according to the result of the verify operation of the nth loop PLn. The second memory cells B cells may be memory cells determined to be in the second state mode DPGM Mode according to the result of the verify operation of the nth loop PLn.

In the case of the first memory cells A cells, an MPGM pulse may be applied in the (n+1)th loop PLn+1, and a DPGM pulse may be applied in the (n+2)th loop PLn+2. The first effective bias in the MPGM pulse may be applied to the first memory cells A cells, and the second effective bias in the DPGM pulse may be applied to the first memory cells A cells.

Since the verify step is omitted in the (n+1)th loop PLn+1, the DPGM pulse may be applied to memory cells of which threshold voltage reaches the target program state Target PV in the (n+2)th loop PLn+2, after the MPGM pulse is applied in the (n+1)th loop PLn+1. Therefore, after the (n+2)th loop PLn+2 is performed, a memory cell over-programmed as compared with the target program state Target PV among the first memory cells A cell may occur. The over-programmed memory cell may be a memory cells of which right distribution is degraded.

In the case of the second memory cells B cells, the DPGM pulse may be applied in the (n+1)th loop PLn+1. The second effective bias lower than the first effective bias in the DPGM pulse may be applied to the second memory cells B cells. Since the second effective bias is lower than the first effective bias, a memory cell under-programmed as compared with the target program state Target PV among the second memory cells B cell may occur, after the (n+1)th loop PLn+1 is performed. The under-programmed memory cells may be a memory cell of which left distribution is degraded. In an embodiment, although the program operation of performing the verify operation by using the two verify voltage levels has been described as an example, the number of verify voltages used in the program operation is not limited to this embodiment.

FIG. 10A is a diagram illustrating a distribution of memory cells according to a change in interval between two verify voltages.

Referring to FIG. 10A, in the double verify program operation (Double verify PGM), a verify voltage interval as an interval between the pre-verify voltage Vvfyp and the main verify voltage Vvfym may be adjusted.

In accordance with an embodiment, the verify voltage interval may be adjusted from a target loop among a plurality of loops. The target loop may be a loop predetermined through a prior test result. The verify voltage interval may be changed from a default verify voltage interval. Since the main verify voltage Vvfym of the two verify voltages is a verify voltage corresponding to a target state of a program operation, the main verify voltage Vvfym may have a fixed value. Therefore, the pre-verify voltage Vvfyp may become low or high to adjust the verify voltage interval.

In FIG. 10A, the default verify voltage interval may be Vvfym-Vvfyp.

In an embodiment, in order to allow the verify voltage interval to be further narrowed than the default verify voltage interval, the pre-verify voltage may increase from Vvfyp to Vvfyp″. At Vvfym-Vvfyp″ as the narrowed verify voltage interval, the number of first memory cells A cells belonging to a first area A area may increase, and the number of second memory cells B cells belonging to a second area B area may decrease.

In an embodiment, in order to allow the verify voltage interval to be further widened than the default verify voltage interval, the pre-verify voltage may increase from Vvfyp to Vvfyp′. At Vvfym-Vvfyp′ as the widened verify voltage interval, the number of first memory cells A cells belong to the first area A area may decrease, and the number of second memory cells B cells belonging to the second area B area may increase.

Through the embodiment described with reference to FIG. 10A, the memory device adjusts the verify voltage interval, so that the number of first memory cells A cells of which right distribution is degraded and the number of second memory cells B cells of which left distribution is degraded can be adjusted.

FIG. 10B is a diagram illustrating a change in DPGM effective bias according to an increase in level of a bit line voltage connected to target memory cells in accordance with an embodiment of the present disclosure.

Referring to FIG. 10B, a level of the second bit line voltage described with reference to FIGS. 8 and 9 may be changed from a target loop among a plurality of loops. The level of the second bit line voltage may be a DPGM BL bias.

The second bit line voltage before the target loop among the plurality of loops may be a default bit line voltage. A magnitude of the second bit line voltage from the target loop may be changed from the default bit line voltage.

For example, the second bit line voltage from the target loop may become greater than the default bit line voltage. The second bit line voltage from the target loop increases as compared with the default bit line voltage, so that memory cells connected to a bit line to which the second bit line voltage is applied can have an effective bias further decreased than that of a loop before the target loop. Therefore, in a subsequent loop of the target loop, the memory cells connected to the bit line to which the second bit line voltage is applied may be under-programmed as compared with when the default bit line voltage is applied to the bit line.

In an embodiment, the target loop may be a loop predetermined through a prior test. For example, the target loop may be an optimum loop in which a threshold of the memory cells can reach a target program state after a DPGM effective bias is applied. In another embodiment, the target loop may be a loop after a current sensing verify operation passes.

Referring to FIGS. 9 and 10A, the verify voltage interval is narrowed by increasing the pre-verify voltage in the target loop, so that the number of second memory cells B cells belonging to the second area B area can decrease. Thus, the degradation of the left distribution, which is described in FIG. 9, can be reduced.

Referring to FIGS. 9 and 10B, the effective bias is decreased by increasing the second bit line voltage as compared with the default bit line voltage in a subsequent loop of the target loop, so that the number of memory cells over-programmed as compared with the target program state Target PV in the (n+2)th loop PLn+2 among the first memory cells A cells can decrease. Thus, the degradation of the right distribution, which is described in FIG. 9, can be reduced.

In an embodiment, although the program operation of performing the verify operation by using the two verify voltage levels has been described as an example, the number of verify voltages used in the program operation is not limited to this embodiment.

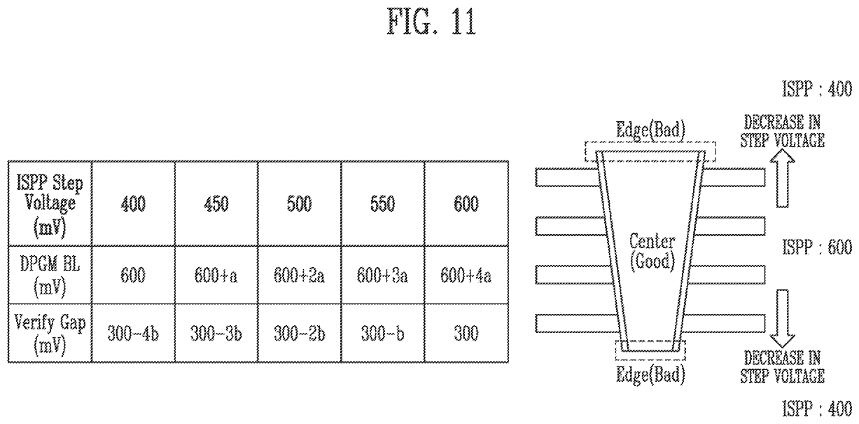

FIG. 11 is a diagram illustrating a default verify voltage interval according to a magnitude of a step voltage and a magnitude of a default bit line voltage applied to a bit line connected to second memory cells.

Referring to FIGS. 5 and 11, the default verify voltage interval and the default bit line voltage may be set according to the magnitude of the step voltage. For example, the default verify voltage interval may be set to become wider as the magnitude of the step voltage increases or becomes larger. The magnitude of the default bit line voltage may be set to become greater as the magnitude of the step voltage increases.

The verify voltage information described with reference to FIG. 2 may be information on a default verify voltage interval corresponding to each of the plurality of step voltages. The bit line voltage information may be information on a default bit line voltage corresponding to each of the plurality of step voltages.

The magnitude of the step voltage described with reference to FIG. 5 may be changed according to a position of a selected word line connected to target cells.

In a structure of a 3D memory cell, a characteristic of a memory cell located at the center of the structure may be satisfactory, and a characteristic of a memory cell located at an edge of the structure might not be good. When the characteristic of the memory cell is not good, the magnitude of the step voltage may be decreased to improve a threshold voltage distribution.

Therefore, in a program operation on the memory cell located at the center, the magnitude of the step voltage may be set to increase. In a program operation on the memory cell located at the edge, the magnitude of the step voltage may be set to decrease.

In another embodiment, the program speed of a memory cell included in a memory block may be changed according to a program and erase count as a number of times a program operation and an erase operation are performed on the memory block. The degradation of the memory cell may increase as the program and erase count increases. Therefore, the memory device may decrease the magnitude of the default bit line voltage as the program and erase count increases to reduce influence of an effective bias on the memory cell as the program and erase count increases.

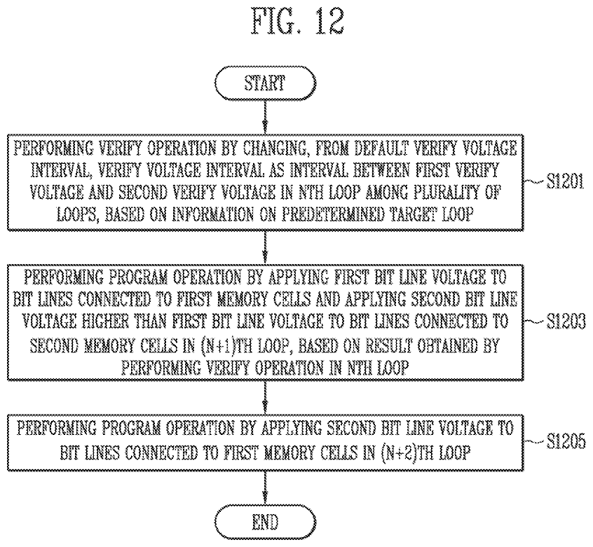

FIG. 12 is a flowchart illustrating an operating method of the memory device in accordance with an embodiment of the present disclosure.

In step S1210, the memory device may perform a verify operation by changing, from a default verify voltage interval, a verify voltage interval as an interval between a first verify voltage and a second verify voltage in an nth loop among a plurality of loops, based on information on a predetermined target loop.

In step S1203, the memory device may perform a program operation by applying a first bit line voltage to bit lines connected to first memory cells and applying a second bit line voltage higher than the first bit line voltage to bit lines connected to second memory cells in an (n+1)th loop, based on a result obtained by performing the verify operation in the nth loop.

In step S1205, the memory device may perform a program operation by applying the second bit line voltage to the bit lines connected to the first memory cells in an (n+2)th loop.

In accordance with an embodiment of the present disclosure, there can be provided a memory device capable of reducing distribution degradation in a program operation of omitting a verify operation in a second half loop, in a program operation method in which a program operation is performed by using two verify voltages.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not to restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a plurality of memory cells;
a peripheral circuit configured to perform a program operation including a plurality of loops each including a program voltage apply step of applying a program voltage to target cells among the plurality of memory cells and a verify step of verifying whether the target cells have been programmed by using a first verify voltage and a second verify voltage greater than the first verify voltage; and
a program operation controller configured to control the peripheral circuit to perform the program operation,
wherein the program operation controller includes:
a verify voltage controller configured to change a verify voltage interval as an interval between the first verify voltage and the second verify voltage from a predetermined target loop among the plurality of loops; and
a bit line voltage controller configured to control the peripheral circuit to apply a first bit line voltage to bit lines connected to first memory cells having a threshold voltage lower than the first verify voltage among the target cells and apply a second bit line voltage higher than the first bit line voltage to bit lines connected to second memory cells having a threshold voltage which is one of higher than and equal to the first verify voltage and is lower than the second verify voltage among the target cells in the program voltage apply step of an (n+1)th loop, and apply the second bit line voltage to the bit lines connected to the first memory cells in the program voltage apply step of an (n+2)th loop, based on a verify result in the verify step of an nth loop as the target loop among the plurality of loops,
wherein n is a natural number that is one of equal to and greater than 2.

2. The memory device of claim 1, wherein the program operation controller further includes a program setting information storage configured to store target loop information as information on the target loop.

3. The memory device of claim 1, wherein each of the (n+1)th loop and the (n+2)th loop includes the program voltage apply step.

4. The memory device of claim 1, further comprising a current sensing circuit configured to count a fail bit number as a number of cells which have program-failed among the target cells,
wherein the bit line voltage controller controls the peripheral circuit to allow the second bit line voltage to be further increased than a default bit line voltage in a program voltage apply step of the (n+1)th loop and the (n+2)th loop.

5. The memory device of claim 4, wherein the bit line voltage controller sets the default bit line voltage according to a program and erase count as a number of times a program operation and an erase operation are performed on a memory block including the target cells.

6. The memory device of claim 4, wherein the nth loop is a pass loop as a loop in which the fail bit number is one of equal to and smaller than a reference number among the plurality of loops.

7. The memory device of claim 1, wherein the verify voltage controller changes the verify voltage interval in the nth loop to be narrower than a default verify voltage interval as a verify voltage interval in a first loop to an (n−1)th loop among the plurality of loops.

8. The memory device of claim 7, wherein the verify voltage controller narrows the verify voltage interval by increasing a level of the first verify voltage in the nth loop.

9. The memory device of claim 2, wherein the program operation controller controls the peripheral circuit to perform the program operation by applying a program voltage increased by a step voltage as a loop increases to a selected word line connected to the target cells.

10. The memory device of claim 9, wherein the program setting information storage stores default verify voltage information as information on a default verify voltage interval corresponding to a plurality of step voltages and default bit line voltage information as information on a default bit line voltage of the second bit line voltage corresponding to the plurality of step voltages.

11. The memory device of claim 10, wherein the verify voltage controller sets the default verify voltage interval according to a magnitude of the step voltage, based on the default verify voltage information.

12. The memory device of claim 11, wherein the verify voltage controller sets the default verify voltage interval to become wider as the magnitude of the step voltage increases.

13. The memory device of claim 9, wherein the program operation controller sets a magnitude of the step voltage according to a position of the selected word line connected to the target cells among a plurality of word lines connected to the plurality of memory cells.

14. The memory device of claim 9, wherein the program operation controller sets a magnitude of the step voltage according to a program speed of the target cell.

15. The memory device of claim 10, wherein the bit line voltage controller sets the default bit line voltage according to a magnitude of the step voltage, based on the default bit line voltage information.

16. The memory device of claim 15, wherein the bit line voltage controller sets the default bit line voltage to become greater as the magnitude of the step voltage increases.

17. The memory device of claim 1, wherein the first bit line voltage includes a ground voltage.

18. A method of operating a memory device for performing a program operation of applying a program voltage increased by a step voltage as a loop increases to a word line connected to target cells among a plurality of memory cells and performing a verify operation on the target cells by using a first verify voltage and a second verify voltage, the method comprising:
performing the verify operation by changing, to a target interval, a verify voltage interval as an interval between the first verify voltage and the second verify voltage in an nth loop among a plurality of loops from a default verify voltage interval as a verify voltage interval in a first loop to an (n−1)th loop among the plurality of loops, based on information on a predetermined target loop;
performing the program operation by applying a first bit line voltage to bit lines connected to memory cells having a threshold voltage lower than the first verify voltage and applying a second bit line voltage higher than the first bit line voltage to bit lines connected to second memory cells having a threshold voltage which is one of greater than and equal to the first verify voltage and is lower than the second verify voltage in an (n+1)th loop among the plurality of loops, based on a result obtained by performing the verify operation in the nth loop; and
performing a program operation by applying the second bit line voltage to the bit lines connected to the first memory cells in a (n+2)th loop among the plurality of loops
wherein n is a natural number that is one of equal to and greater than 2.

19. The method of claim 18, further comprising changing the default verify voltage interval according to a magnitude of the step voltage.

20. The method of claim 18, further comprising setting a magnitude of the second bit line voltage to be greater than a default bit line voltage as a second bit line voltage up to the nth loop, after the target loop.

21. A memory device comprising:
a plurality of memory cells;
a peripheral circuit configured to perform a program operation including a plurality of loops each including a program voltage apply step of applying a program voltage to target cells among the plurality of memory cells and a verify step of verifying whether the target cells have been programmed by using a plurality of verify voltages; and
a program operation controller configured to control the peripheral circuit to change an interval between the plurality of verify voltages from a default interval to a target interval from a predetermined target loop among the plurality of loops, to determine each of bit line voltages to be applied to bit lines of the target cells in a program voltage apply step of an (n+1)th loop and an (n+2)th loop, based on a verify result in an nth loop as the target loop, and to omit performance of a verify step in the (n+1)th loop and the (n+2)th loop,
wherein n is a natural number that is one of equal to and greater than 2.

22. The memory device of claim 21, wherein the program operation controller determines which states a plurality of states defined by the plurality of verify voltages threshold voltages of the target cells respectively belong to,
wherein the plurality of verify voltages include a first verify voltage, a second verify voltage, and a third verify voltage, and
wherein the plurality of states include:
a first state corresponding to a threshold voltage lower than the first verify voltage;
a second state corresponding to a threshold voltage which is one of greater than and equal to the first verify voltage and is lower than the second verify voltage;
a third state corresponding to a threshold voltage which is one of greater than and equal to the second verify voltage and is lower than the third verify voltage; and
a fourth state corresponding to a threshold voltage that is one of greater than and equal to the third verify voltage.

23. The memory device of claim 22, wherein the program operation controller controls the peripheral circuit to apply a first bit line voltage to bit lines connected to first memory cells belonging to the first state, apply a second bit line voltage to bit lines connected to second memory cells belonging to the second state, apply a third bit line voltage to bit lines connected to third memory cells belonging to the third state, and apply a fourth bit line voltage to bit lines connected to fourth memory cells belonging to the fourth state, in the (n+1)th loop, and to apply the second bit line voltage to the bit lines connected to the first memory cells, apply the third bit line voltage to the bit lines connected to the second memory cells, and apply the fourth bit line voltage to the bit lines connected to the third memory cells, in the (n+2)th loop.

24. The memory device of claim 23, wherein the first bit line voltage is lower than the second bit line voltage,
the second bit line voltage is lower than the third bit line voltage, and
the third bit line voltage is lower than the fourth bit line voltage.

25. The memory device of claim 22, wherein the first bit line voltage is a ground voltage.

26. The memory device of claim 22, wherein the fourth bit line voltage is a program inhibit voltage for inhibiting programming on the target cells.

27. The memory device of claim 21, wherein the program operation controller includes a program setting information storage configured to store target loop information as information on the target loop.

28. The memory device of claim 21, wherein the target interval is narrower than the default interval.

29. The memory device of claim 23, wherein the second bit line voltage is greater than a voltage applied in a program voltage apply step of the nth loop to a bit line connected to memory cells having a threshold voltage which is one of greater than and equal to the first verify voltage and is lower than the second verify voltage in a verify step of an (n−1)th loop, and
the third bit line voltage is greater than a voltage applied in the program voltage apply step of the nth loop to a bit line connected to memory cells having a threshold voltage which is one of greater than and equal to the second verify voltage and is lower than the third verify voltage in the verify step of the (n−1)th loop.
